(19) United States
(12) Patent Application Publication
(10) Pub. No.: US 2010/0025842 A1
(43) Pub. Date: Feb. 4, 2010

(54) SEMICONDUCTOR MODULE AND SEMICONDUCTOR DEVICE

(75) Inventors: Tetsuya YAMAMOTO, Osaka (JP); Mayumi NAKASATO, Osaka (JP); Yoshio OKAYAMA, Osaka (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 12/533,832

(22) Filed: Jul. 31, 2009

(30) Foreign Application Priority Data
Jul. 31, 2008 (JP) 2008-198939

(51) Int. Cl. H01L 23/52; H01L 23/488

(52) U.S. Cl. 257/692; 257/737; 257/E23.023; 257/E23.141

(57) ABSTRACT

A semiconductor module includes an insulating resin layer, a wiring layer provided on one main surface S1 of the insulating layer, and bump electrodes, electrically connected to the wiring layer, which are protruded on the insulating resin layer side from the wiring layer. Element electrodes provided on a semiconductor element are electrically connected to the bump electrodes. Solder parts are provided in predetermined positions of the wiring layer. The ratio (H2/H1) of the height H2 of the bump electrode over the height H1 of the solder part is 50% or below.

This application is based upon and claims the benefit of priority from the prior Japanese Patent Application No. 2008-198939, filed on Jul. 31, 2008, the entire contents of which are incorporated herein by reference.

### BACKGROUND OF THE INVENTION

1. Field of the Invention

The present invention relates to a semiconductor module having a semiconductor element, and a semiconductor device having the semiconductor module.

2. Description of the Related Art

Portable electronic devices, such as mobile phones, PDAs, DVCs and DSCs, are gaining increasing sophistication in functions and features. And to be accepted by the market, they have to be smaller in size and lighter in weight, and for the realization thereof, there is a growing demand for highly-integrated system LSIs. On the other hand, these electronic devices are desired to be easier or handier to use, and therefore the LSIs used in those devices are required to be more functionally sophisticated and better performing. For this reason, the higher integration of LSI chips is causing increases in I/O count, which in turn generates demand for smaller packages. To satisfy both these requirements, it is strongly desired that semiconductor packages suited for the high board density packaging of semiconductor components be developed. To meet such needs, a variety of packaging technologies called CSP (Chip Size Package) are being developed.

A conventional method of manufacturing semiconductor modules of CSP type has been proposed as a method to reduce the number of processes.

In the conventional semiconductor modules, improvement of reliability of connection between rewiring and bump electrodes has been attempted by integrally forming the rewiring and the bump electrodes with each other. However, the effect of solder connection parts on the connection reliability is not known in the case when the rewiring and the bump electrodes are formed integrally, and there is room for improvement of connection reliability for heat cycle of the solder connection parts.

### SUMMARY OF THE INVENTION

The present invention has been made in view of the foregoing problems to be resolved, and a purpose thereof is to provide a technology for improving the connection reliability between a packaging board and solder parts to be connected thereto in a semiconductor module where a wiring layer and a bump electrode are formed integrally with each other and a semiconductor device having the semiconductor module.

One embodiment of the present invention provides a semiconductor module. This semiconductor module comprises: a semiconductor substrate; an element electrode formed on one main surface of the semiconductor substrate; a wiring layer disposed on a main surface side of the semiconductor substrate through an insulating resin layer; a bump electrode connected electrically to the wiring layer, protruding on a side of the insulating resin layer from the wiring layer and connected electrically to the element electrode; and a solder part disposed on a surface of the wiring layer opposite to the insulating resin layer, the solder part being spaced apart from the element electrode, wherein the ratio of the bump electrode to the solder part in height is 50% or below.

By employing this embodiment, when warping occurs in the semiconductor substrate due to a temperature rise, the wiring layer becomes deformed according to the warping of the semiconductor substrate. Thus the stress acting on the solder part is mitigated.

In the above-described semiconductor module, the thickness of the semiconductor substrate may be 100 μm or above. Also, the ratio of the bump electrode to the solder part in height may be in the range between 8% and 38%, inclusive. Also, the bump electrode and the wiring layer may be formed integrally with each other.

Another embodiment of the present invention provides a semiconductor device. This semiconductor device comprises: a semiconductor module according to any of the above-described embodiments; and a packaging board on which a electrode pad is formed, wherein the electrode pad and the solder part are bonded together.

It is to be noted that any arbitrary combinations or rearrangement, as appropriate, of the aforementioned constituting elements and so forth are all effective as and encompassed by the embodiments of the present invention.

### BRIEF DESCRIPTION OF THE DRAWINGS

Embodiments will now be described by way of examples only, with reference to the accompanying drawings which are meant to be exemplary, not limiting, and wherein like elements are numbered alike in several Figures in which:

FIG. 1 is a cross-sectional view of a semiconductor device according to an embodiment of the present invention;

FIG. 2 is a cross-sectional view of a semiconductor device model used in a simulation;

FIG. 3 is a graph showing a relationship between the ratio of the height of bump electrode to the height of solder part and the ratio of equivalent stress acting on the solder part, where both the ratios are obtained from simulation runs;

FIG. 4 is a graph showing a relationship between the ratio of equivalent stress and the percentage of increase in fatigue life (rate of increase in reliability); and

FIG. 5 is a graph showing a relationship between the ratio of the height of bump electrode to the height of solder part and the rate of change of equivalent stress acting on the solder part.

### DETAILED DESCRIPTION OF THE INVENTION

The invention will now be described by reference to the preferred embodiments. This does not intend to limit the scope of the present invention, but to exemplify the invention.

Hereinbelow, the embodiments will be described with reference to the accompanying drawings. Note that in all of the Figures the same reference numerals are given to the same components and the description thereof is omitted as appropriate.

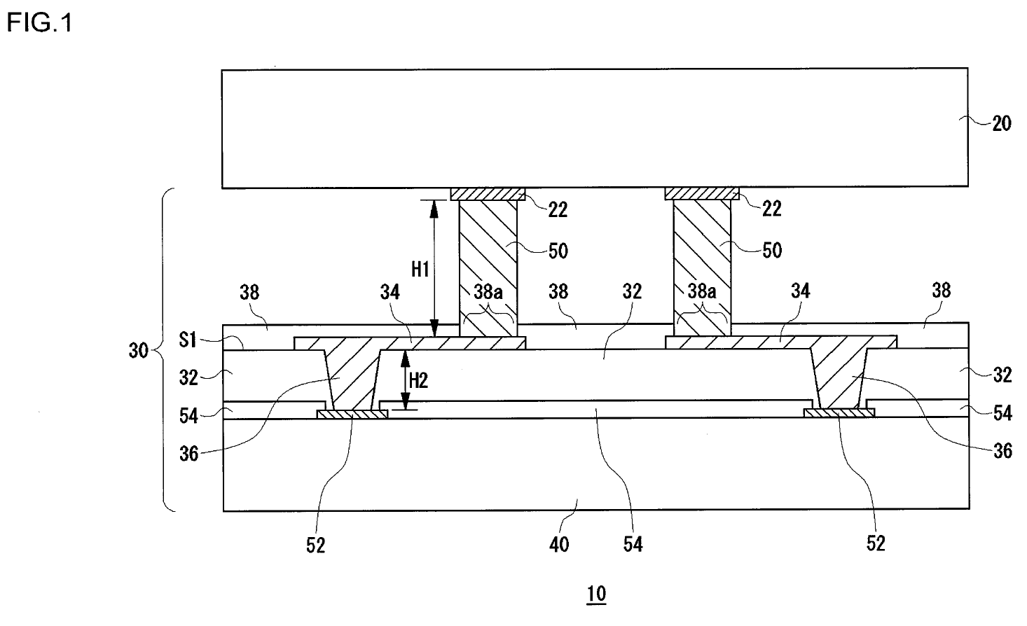

FIG. 1 is a cross-sectional view of a semiconductor device according to an embodiment of the present invention. A semiconductor device 10 includes a packaging board 20 and a semiconductor module 30 mounted on this packaging board 20.

The semiconductor module 30 includes an insulating resin layer 32, a wiring layer 34 provided on one main surface S1 of the insulating resin layer 32, and a bump electrode 36, electrically connected to the wiring layer 34, which is protruded (projected) from the wiring layer 34 toward an insulating resin layer 32 side thereof. The semiconductor module 30 is formed by electrically connecting a semiconductor element 40 to this bump electrode 36.

The insulating resin layer 32 is made of insulating resin and is formed of, for example, a material that develops plastic flow when pressurized. An example of the material that develops plastic flow when pressurized is epoxy thermosetting resin. The epoxy thermosetting resin to be used for the insulating resin layer 32 may be, for example, one having viscosity of 1 kPa·s under the conditions of a temperature of 160° C. and a pressure of 8 MPa. If a pressure of 5 to 15 MPa is applied to this epoxy thermosetting resin at a temperature of 160° C., then the viscosity of the resin will drop to about ⅛ of the viscosity thereof with no pressurization. In contrast to this, an epoxy resin in B stage before thermosetting has no viscosity, similarly to a case when the resin is not pressurized, under a condition that the temperature is less than or equal to a glass transition temperature Tg. And the epoxy resin develops no viscosity even when pressurized under the condition that the temperature is less than or equal to the glass transition temperature Tg. Also, this epoxy thermosetting resin is a dielectric substance having a permittivity of about 3 to 4.

The wiring layer 34 is provided on one main surface S1 of the insulating resin layer 32 and is formed of a conducive material, preferably of a rolled metal or more preferably of a rolled copper. Or the wiring layer 34 may be formed of electrolyte copper or the like. The bump electrode 36 is provided, in a protruding manner, on the insulating resin layer 32 side. In the present embodiment, the wiring layer 34 and the bump electrode 36 are formed integrally with each other but the structure is not particularly limited thereto. A protective layer 38 is provided on a main surface of the wiring layer 34 opposite to the insulating resin layer 32. This protective layer 38 protects the wiring layer 34 against oxidation or the like. The protective layer 38 may be a solder resist layer, for instance. An opening 38a is formed in a predetermined position of the protective layer 38, and the wiring layer 34 is partially exposed there. A solder part 50, which functions as an external connection electrode, is formed within the opening 38a. And the solder part 50 and the wiring layer 34 are electrically connected to each other. The position in which the solder part 50 is formed, namely, the area in which the opening 38a is formed is, for instance, an end where circuit wiring is extended through a rewiring.

The overall shape of the bump electrode 36 may be narrower toward the tip portion thereof. In other words, the side surface of the bump electrode 36 may be tapered. A metallic layer, such as a Ni/Au plating layer, may be provided on a top surface of the bump electrode 36.

The semiconductor device 40 is an active element such as an integrated circuit (IC) or a large-scale integrated circuit (LSI) which is formed on a semiconductor substrate such as a Si substrate.

Element electrodes 52 are provided on a main surface of the semiconductor element 40 at an insulating resin layer 32 side and disposed counter to the bump electrodes 36, respectively. A protective layer 54 is provided on a main surface of the semiconductor element 40 at the insulating resin layer 32 side thereof. This protective layer 54 is provided so that the element electrodes 52 are exposed on the surface thereof. For example, a polyimide may be used for the protective layer 54.

The semiconductor module 30 structured as above is mounted on the packaging board 20 in such a manner that the solder parts 50, such as solder balls, are bonded to electrode pads 22 provided on the packaging board 20, such as a printed circuit board.

The ratio (H2/H1) of the height H2 of the bump electrode 36 to the height H1 of the solder bump 50 is preferably greater than 0% and less than or equal to 50%. The ratio (H2/H1) of the height H2 of the bump electrode 36 to the height H1 of the solder bump 50 is more preferably in the range of 8% to 38%, inclusive. This is because it is presumed that when warping occurs in the semiconductor element 40 due to a temperature rise, having the wiring layer 34 deformed according to the warping of the semiconductor element 40 helps mitigate the stress acting on the solder part 50. In contrast to this, when the height H2 of the bump electrode 36 is zero, namely, when no bump electrode 36 is provided at all, and also when warping occurs in the semiconductor element 40 due to a temperature rise, it is presumed that the solder part 50 becomes deformed a great deal and therefore the stress acing on the solder part 50 becomes greater. On the other hand, as the ratio (H2/H1) of the height H2 of the bump electrode 36 to the height H1 of the solder bump 50 becomes greater than 50%, it is presumed that the occurrence of warping in the semiconductor element 40 due to a temperature rise causes the solder part 50 to be deformed and therefore the stress acting on the solder part 50 increases.

(Analysis of Stress Acting on Solder Parts)

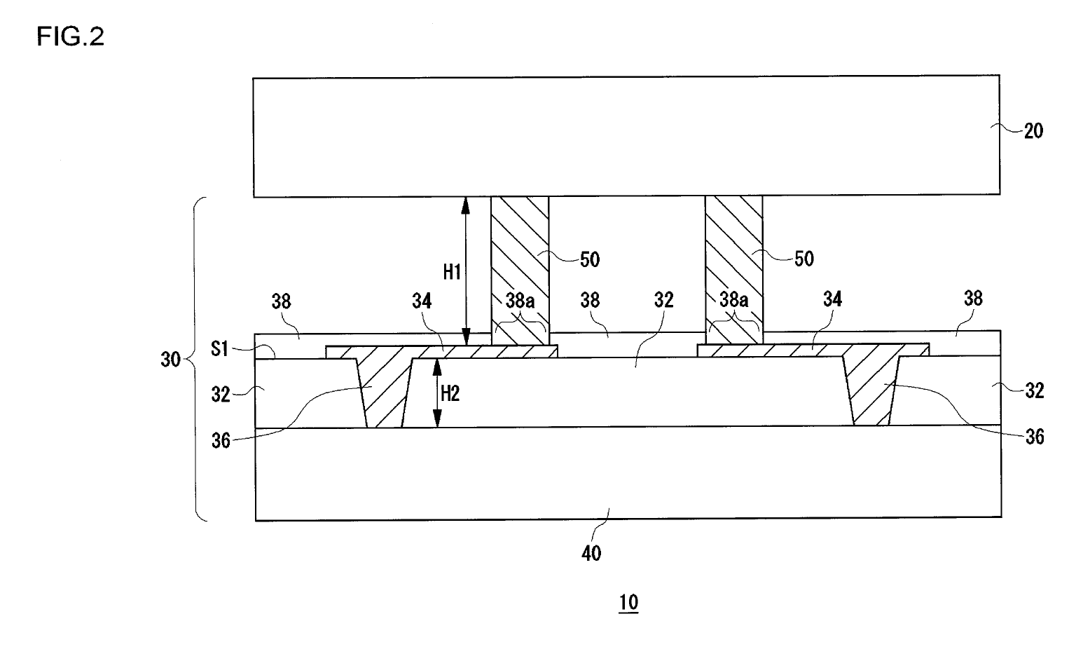

A simulation for the ratio of the bump electrode to the solder in height is performed using a nonlinear P Finite Element Method (e.g., StressCheck Ver. 7.0). FIG. 2 is a cross-sectional view of a semiconductor device model used in the simulation. For the sake of simplicity, the electrode pads 22, the element electrodes 52 and the protective layer 54 shown in FIG. 1 are omitted in FIG. 2. In this simulation, the size of a model for the semiconductor element 40 is ¼ of 5 mm×5 mm (length of each side is 2.5 mm). The conditions used in the simulation are shown in Table 1 and Table 2. Table 1 shows conditions for dimensions of the semiconductor device used in the simulation. Table 2 shows conditions for material characteristics of the semiconductor device used in the simulation.

TABLE 1

| | |
|---|---|
| Thickness of semiconductor element 40 | 50 μm, 100 μm, 300 μm |
| Thickness of insulating resin layer 32 | Equals the height of |
| | bump electrode 36 |
| Thickness of wiring layer 34 | 20 μm |
| Thickness of protective layer 38 | 40 μm |
| Height (H1) of solder part 50 | 120 μm |
| Height (H2) of bump electrode 36 | Variable |
| Thickness of packaging board 20 | 1000 μm |

TABLE 2

| | | | | | Coefficient |
|---|---|---|---|---|---|
| | Young's | | Yield | Tangent | of Thermal |
| | modulus | Poisson | stress | modulus | expansion |
| | (Gpa) | ratio | (MPa) | (MPa) | (ppm/° C.) |
| Wiring | 130 | 0.35 | 100 | 5000 | 17 |
| layer 34 | | | | | |
| Semiconductor | 190 | 0.07 | — | — | 3 |
| element 40 | | | | | |
| Insulating | 1.1 | 0.35 | — | — | 140 |
| resin | | | | | |
| layer 32 | | | | | |
| Protective | 3.1 | 0.31 | — | — | 58 |
| layer 38 | | | | | |
| Packaging | 27 | 0.2 | — | — | 12 |
| board 20 | | | | | |
| Solder | 40.1 | 0.35 | — | — | 23 |
| part 50 | | | | | |

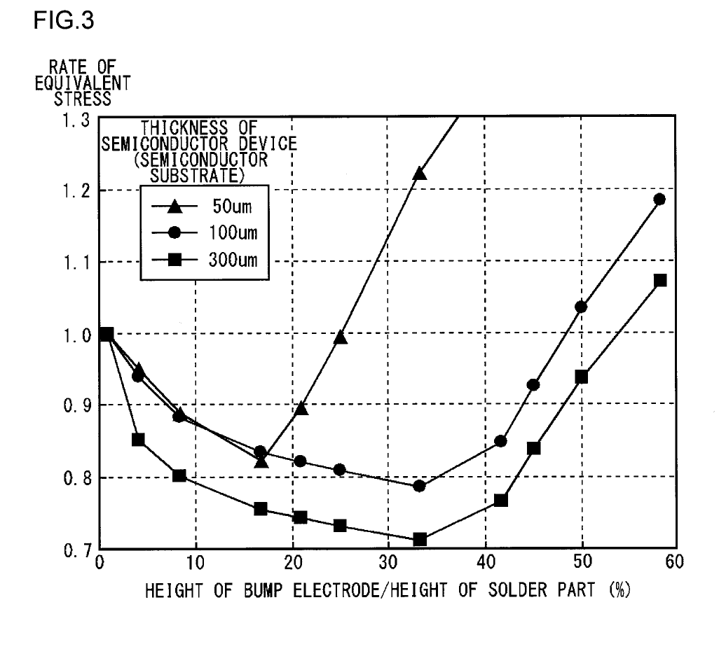

FIG. 3 is a graph showing a relationship between the ratio of the height H2 of bump electrode to the height H1 of solder part and the ratio of equivalent stress acting on the solder part, wherein both the ratios are acquired from simulation runs. Note that the ratio of equivalent stress is a value based on the equivalent stress acting on the solder part when the height H2 of the bump electrode is set to zero. As shown in FIG. 3, when the thickness of the semiconductor element (i.e., the thickness of the semiconductor substrate) is 100 μm or above and when the ratio (H2/H1) of the height H2 of bump electrode to the height H1 of solder part is in the range of 0% and 50% (inclusive), it is verified that the ratio of equivalent stress acting on the solder part becomes less than 1. In other words, it is verified that the equivalent stress acting on the solder part decreases as compared with when the height H2 of bump electrode is set to zero.

If it is assumed that the increased amount of deformation (plastic strain range) is proportional to the maximum equivalent stress σₘₐₓ, a fatigue life (the number of repetitions required to cause fracture) Nf in a heat cycle test can be evaluated by the following Equation (1)

$${N}_{f} = {( \frac{0.521 E}{{σ}_{max}} )}^{\frac{1}{0.517}} \qquad ( 1 )$$

In Equation (1), E is the young's modulus of the solder part. Equation (1) indicates that N_{f} is proportional to (1/σₘₐₓ)^{1/0.517}. If the equivalent stress varies from σ₁ to σ₂ (σ₁>σ₂), the percentage of increase in fatigue life, denoted by N′, can be expressed by the following Equation (2). Here, σ₁ indicates an equivalent stress acting on the solder part when the height of bump electrode is zero, whereas σ₂ indicates an equivalent stress acting on the solder part when the height of bump electrode is set to a certain value.

$${N}^{′} = ( {( \frac{{σ}_{1}}{{σ}_{2}} )}^{\frac{1}{0.517}} - 1 ) \times 100 \qquad ( 2 )$$

When the ratio of equivalent stress is σ₂/σ₁, the percentage of increase in fatigue life can be expressed by the following Equation (3)

$${N}^{′} = ( {( \frac{1}{〈 Ratio of equuivalent stress 〉} )}^{\frac{1}{0.517}} - 1 ) \times 100 \qquad ( 3 )$$

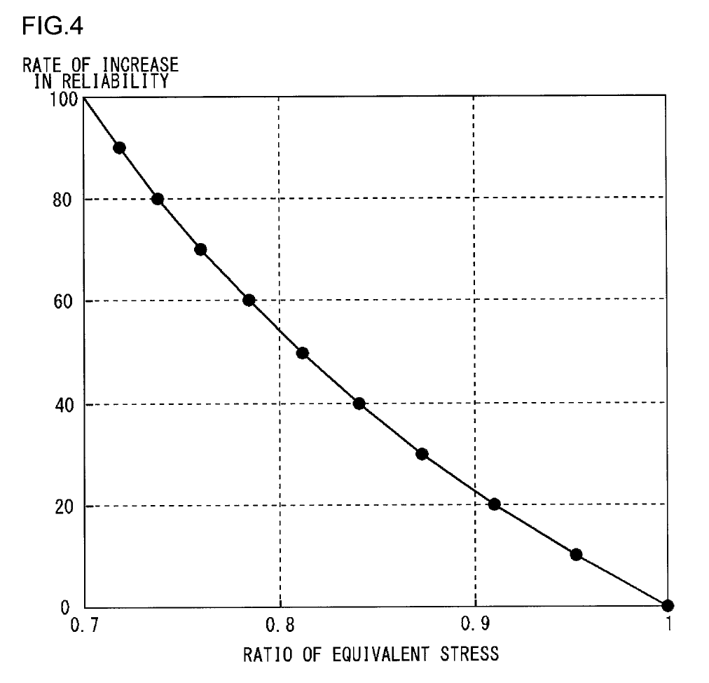

FIG. 4 is a graph showing a relationship between the ratio of equivalent stress and the percentage of increase in fatigue life (rate of increase in reliability) evaluated by the above Equations (1) to (3). It is seen from FIG. 4 that the percentage of increase in fatigue life rises as the ratio of equivalent stress decreases. Conversely, it is found that the percentage of increase in fatigue life decreases as the ratio of equivalent stress increases. That is, as the ratio of equivalent stress increases to a large extent, the percentage of increase in fatigue life decreases in proportion thereto. Note that when the ratio of equivalent stress is about 0.91, the percentage of increase in fatigue life is 20%. Note also that when the ratio of equivalent stress is about 0.78, the percentage of increase in fatigue life is 60%.

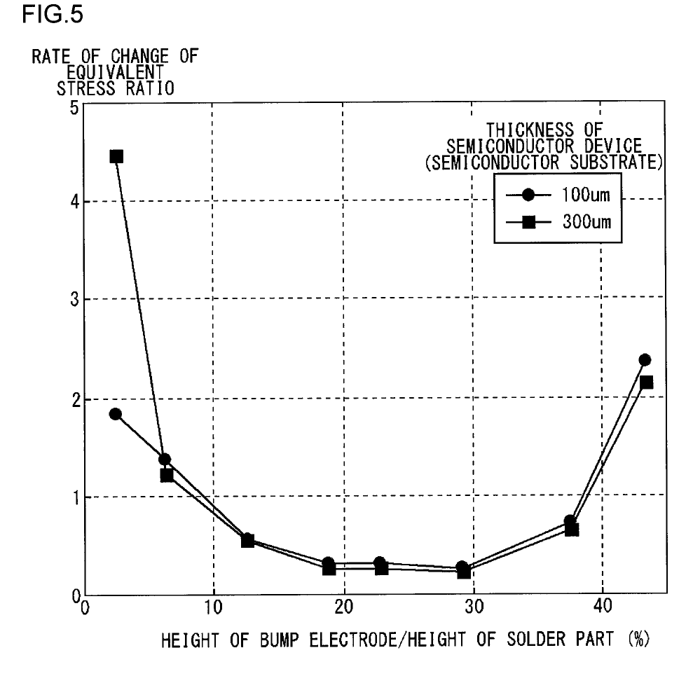

FIG. 5 is a graph showing a relationship between the ratio of the height of bump electrode to the height of solder part and the rate of change of equivalent stress acting on the solder part. The semiconductor elements whose thickness are 100 μm and 300 μm are subjected to this simulation. If the equivalent stress acting on the solder part is defined by σ and the ratio of the height H2 of bump electrode to the height H1 of solder part is defined by s, the rate of change of equivalent stress ratio is expressed by |Δσ/Δs| which corresponds to a slope of the curve shown in FIG. 3.

As evident from FIG. 5, it is found that as the rate of change of equivalent stress ratio exceeds 1, depicted is a bathtub curve characterized by the properties that the rate of change of equivalent stress ratio increases sharply. On the other hand, in a range where the rate of change of equivalent stress ratio is less than or equal to 1, it is found from FIG. 5 that the ratio of equivalent stress takes a minimum value in this range and the variation in the rate of change of equivalent ratio gets smaller even if the ratio of the height H2 of bump electrode to the height H1 of solder varies. Thus it is found here that the percentage of increase in fatigue life (rate of increase in reliability) stays stable in this range. Hence, it is preferable that the range of the rate of change of equivalent stress ratio be 1 or below. The ratio of the height H2 of bump electrode to the height H1 of solder part corresponding to this range is greater than or equal to 8% and less than or equal to 38%.

The present invention is not limited to the above-described embodiments only, and it is understood by those skilled in the art that various modifications such as changes in design may be made based on their knowledge and the embodiments added with such modifications are also within the scope of the present invention.

For example, an insulating layer formed by epoxy resin or the like may be provided between the semiconductor element 40 and the protective layer 54.

What is claimed is:

1. A semiconductor module, comprising:
a semiconductor substrate;
an element electrode formed on one main surface of said semiconductor substrate;
a wiring layer disposed on a main surface side of said semiconductor substrate through an insulating resin layer;
a bump electrode connected electrically to said wiring layer, protruding on a side of the insulating resin layer from said wiring layer and connected electrically to said element electrode; and
a solder part disposed on a surface of said wiring layer opposite to the insulating resin layer, said solder part being spaced apart from said element electrode,
wherein the ratio of said bump electrode to said solder part in height is 50% or below.

2. A semiconductor module according to claim 1, wherein the thickness of said semiconductor substrate is 100 μm or above.

3. A semiconductor module according to claim 1, wherein the ratio of said bump electrode to said solder part in height is in the range of 8% to 38%, inclusive.

4. A semiconductor module according to claim 2, wherein the ratio of said bump electrode to said solder part in height is in the range of 8% to 38%, inclusive.

5. A semiconductor module according to claim 1, wherein said bump electrode and said wiring layer are formed integrally with each other.

6. A semiconductor module according to claim 2, wherein said bump electrode and said wiring layer are formed integrally with each other.

7. A semiconductor module according to claim 3, wherein said bump electrode and said wiring layer are formed integrally with each other.

8. A semiconductor device, comprising:
a semiconductor module according to claim 1; and
a packaging board on which a electrode pad is formed,
wherein the electrode pad and said solder part are bonded together.
